(19) United States
(12) Patent Application Publication
(10) Pub. No.: US 2003/0189151 A1
(43) Pub. Date: Oct. 9, 2003

(54) Apparatus for mounting shroud to ceiling bracket and method of making same

(76) Inventor: Cheng Ming Hsing, Kaohsiung (CN)

Correspondence Address: SIDLEY AUSTIN BROWN & WOOD LLP, 717 NORTH HARWOOD, SUITE 3400, DALLAS, TX, 75201, US

(21) Appl. No.: 10/116,015

(22) Filed: Apr. 3, 2002

(51) Int. Cl. H05K 5/02

(52) U.S. Cl. 248/345

(57) ABSTRACT

A mounting assembly for a ceiling fan including a frame that can be mounted to a ceiling, and a shroud for covering the frame. The shroud has a flange with a projection provided thereon, whereas the frame has a surface with a receptacle formed therein. Accordingly, the shroud and the frame can be positioned such that the projection on the shroud and the receptacle on the frame can mate in order to secure the shroud to the frame.

### FIELD OF THE INVENTION

The present invention relates to an assembly for mounting a ceiling fan to a surface.

### BACKGROUND OF THE INVENTION

Ceiling fans are generally mounted to a ceiling according to a flush mount configuration or according to a hanging mount configuration. In the flush-mounting configuration, the ceiling fan motor is mounted close, i.e., flush, against the ceiling, whereas with a hanging mount, the ceiling fan motor is mounted on a downrod, which hangs downwardly from a position on the ceiling. In the configurations described above, a mounting assembly including a bracket fitting and a bracket canopy can be used to both protect, and decoratively cover the position where the fan assembly is mounted on the ceiling.

Generally, the bracket fitting is attached to the ceiling with screws. The downrod of the fan is positioned to hang downwardly from the bracket fitting, and the bracket canopy is used to cover the attachment of the bracket fitting to the ceiling, and the downrod to the bracket fitting. Conventionally, the bracket canopy is attached to the bracket fitting with screws which are driven through aligning holes in each of the bracket fitting and the bracket canopy, in a direction that is generally parallel to the surface on which the bracket fitting is mounted.

The conventional practices for attaching a bracket canopy to a bracket fitting as described above are especially difficult because of the positioning of the bracket fitting and the bracket canopy in relation to the surface of the ceiling on which the bracket is being mounted. More specifically, because screws are driven through the bracket fitting and the bracket canopy, in a direction that is parallel to the surface of the ceiling, and because the screws are positioned within such close proximity to the surface of the ceiling, the surface of the ceiling becomes an impediment which limits the range of motion of a user. Consequently, the amount of rotation of a screwdriver being used by the user is also limited. Thus, the job of mounting a bracket canopy to a bracket fitting can be tedious and time consuming because of the limitations of the hardware.

### BRIEF SUMMARY OF THE INVENTION

Accordingly, the present invention provides a mounting assembly for a ceiling fan which simplifies the mounting of a bracket cover to a bracket fitting that is secured to a surface.

In one aspect of the invention, a shroud and a frame are formed in a complimentary manner to enable the shroud to cover, or fit over, the frame.

In another aspect of the invention, a mounting assembly comprises a frame for mounting a fan to a surface, wherein a surface of the frame is provided with a receptacle therein, and a shroud for covering the frame, wherein an inner surface of the shroud is provided with a projection for mating with the receptacle.

In another aspect of the invention, an assembly for a ceiling fan comprises a frame having a first surface and a second surface, wherein the second surface is provided with a receptacle therein, and a shroud having a flange with an inner surface that has a projection provided thereon for mating with the receptacle, wherein the shroud can be positioned to cover the frame such that the inner surface of the flange is positioned adjacent to the second surface of the frame, and the projection of the shroud can be inserted into the receptacle of the frame.

In a further aspect of the invention, a method for making an assembly for attaching a ceiling fan to a surface comprises the steps of providing a frame having a first surface and a second surface, and forming a shroud that is capable of covering the frame when the first surface of the frame is positioned on a surface, wherein a projection is provided on an inner surface of the shroud, and a receptacle for mating with the projection is provided in the second surface of the frame.

### BRIEF DESCRIPTION OF THE DRAWINGS

Other advantages and features of the invention will become more apparent with reference to the following detailed description of the presently preferred embodiment thereof in connection with the accompanying drawings, wherein like reference numbers have been applied to like elements, in which:

FIG. 1 illustrates a frame and shroud according to the present embodiment;

FIG. 2 illustrates the shroud positioned over the frame according to the present embodiment; and

FIG. 3 illustrates the shroud secured to the frame according to the present embodiment.

### DETAILED DESCRIPTION OF THE INVENTION

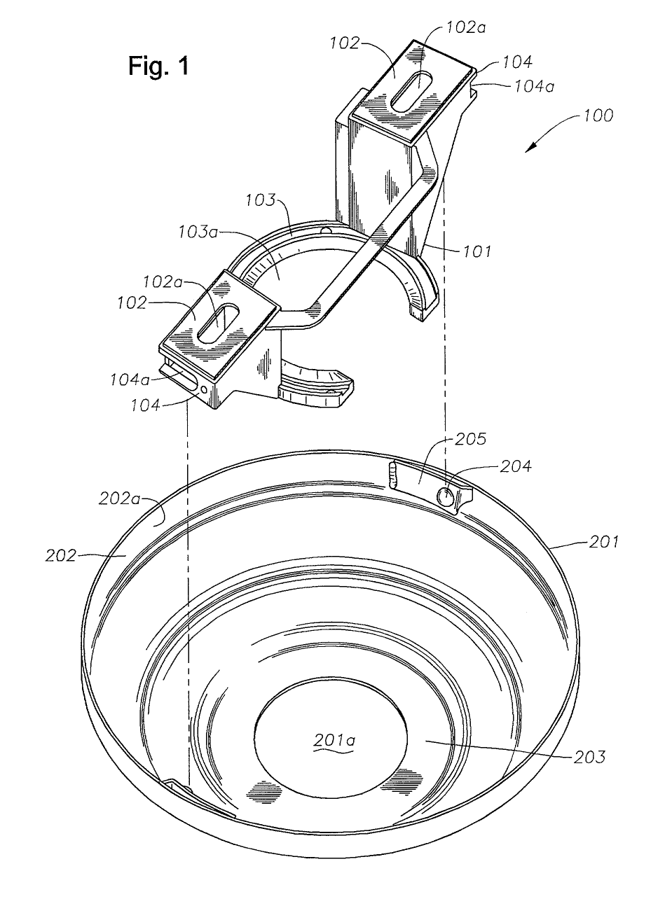

In accordance with the present invention, FIG. 1 illustrates a mounting assembly 100 for mounting a ceiling fan to a surface. As shown, mounting assembly 100 includes a frame 101 and a shroud 201. According to the present embodiment, shroud 201 and frame 101 are formed in a complementary manner to enable shroud 201 to fit over, or cover, frame 101. Furthermore, in accordance with an aspect of the present invention, shroud 201 can be secured to frame 101 with the use of a projection 204 provided in shroud 201, and a receptacle 104a provided in frame 101. Hereinafter, mounting assembly 100 will be described with reference to a surface of a ceiling, however, as will be understood, mounting assembly 100 can be mounted on other surfaces.

As shown in FIG. 1, frame 101 can be of a bracket-type frame having a first surface 102, which, according to an embodiment, can be used to mount frame 101 to hang from a surface of a ceiling, or to hang from an electrical supply box. More specifically, first surface 102 has a hole 102a through which a screw, or any other substitute, can be inserted to mount frame 101 onto a surface. In one embodiment, the screw can be driven upwardly through hole 102a, into the surface of the ceiling, or the power supply box, on which frame 101 will be mounted. Accordingly, first surface 102 can be positioned flush against the surface of the ceiling. Thus, according to the above description, a portion of frame 101 projects from the surface on which frame 101 is mounted, and in particular, in the present embodiment, a portion of frame 101 hangs downwardly from the surface of the ceiling.

According to the present embodiment, the portion of frame 101 hanging downwardly terminates with a skirt 103, which at least partially defines an opening 103a at one end of frame 101. In one embodiment, skirt 103 and opening 103a are suitable for containing an articulating member in which a downrod can be positioned to hang downwardly from frame 101 when frame 101 is attached to a ceiling. Thus, frame 101 includes a first surface 102 at a first end of frame 101 for mounting frame 101 to a ceiling, or a power supply box, and a skirt 103 at a second end of frame 101 suitable for mounting a downrod assembly to hang from frame 101. Also, although not shown, in the present embodiment, a lower surface of skirt 103, relative to the surface of the ceiling on which frame 101 is mounted, is generally a flat surface, and is provided in a plane that is generally parallel to surface 102 of frame 101. Skirt 103, however, is not limited to any particular shape.

As shown in FIG. 1, shroud 201 can be formed by a hollow body that has a contour that is generally conical, with a flange 202 at a first end and a rim surface 203 at a second end. More specifically, while a substantial portion of the body of shroud 201 is inclined, relative to a surface on which mounting assembly 100 will be mounted, flange 202 is formed to be generally perpendicular to a surface on which mounting assembly 100 will be mounted. Rim surface 203 on the other hand, is generally parallel to a surface on which ceiling mount assembly 100 will be mounted, and defines the boundaries of an aperture 201a through shroud 201. However, the above description of shroud 201 represents only an exemplary form of shroud 201 and does not limit the configuration of shroud 201.

As previously stated, a size of shroud 201 of mounting assembly 100 is preferably sufficient to enable frame 101 to be housed, or at least partially covered, by shroud 201. More specifically, in the present embodiment, a diameter defined by flange 202 of shroud 201 is greater than a length of frame 101, such that shroud 201 can be positioned over frame 101. In a preferred embodiment, a second surface 104 of frame 101, provided at each side of frame 101, is curved to correspond with a curve of flange 202. Further, a depth of shroud 201, from an edge of flange 202 to rim surface 203, generally corresponds to the height of frame 101, from first surface 102 to a lower surface of skirt 103. Thus, when shroud 201 is positioned over frame 101, skirt 103 will be positioned on, or adjacent to, rim surface 203, and second surface 104 will be positioned adjacent to an inner surface 202a of flange 202. Further, because the inner diameter of flange 202 is slightly larger than a length of frame 101, shroud 201 can be rotated around frame 101, or vice-versa, frame 101 can be rotated in shroud 201.

As described above, in accordance with one aspect of the present invention, a projection 204 on shroud 201 and a receptacle 104a in frame 101 can be used to aid in securing shroud 201 to frame 101. Accordingly, shroud 201 is provided with projection 204 which, according to the present embodiment, is positioned on a movable element 205. As FIG. 1 shows, movable element 205 is positioned on inner surface 202a of flange 202. In one embodiment, movable element 205 is a spring element or biasing element that positions projection 204 on inner surface 202a of flange 202 in a resilient manner. Movable member 205 and projection 204 can be provided on inner surface 202a of flange 202 by any means, including welding or adhesives. In an alternate embodiment, projection 204 can be provided directly on surface 202a without being positioned on movable member 205. Further, as shown in the present embodiment, a plurality of movable members 205 and projections 204 can be provided at diametrical positions of inner surface 202a of flange 202. Thus, any number of configurations can be used.

Correspondingly, the present embodiment provides that receptacle 104a is provided in second surface 104 on an exterior of frame 101. Receptacle 104a is generally a U-shaped slot, which begins at an interior position of second surface 104 and extends and opens to an edge of second surface 104, as shown. In accordance with the present embodiment, a size of each receptacle 104a generally corresponds to a size of projection 204 of shroud 201. Further, in a preferred embodiment, a plurality of receptacles 104a can be provided in frame 101 to correspond with a plurality of projections 204 provided in shroud 201. Thus, shroud 201 can be secured to frame 101 at plural positions, which strengthens the mounting of shroud 201 to frame 101.

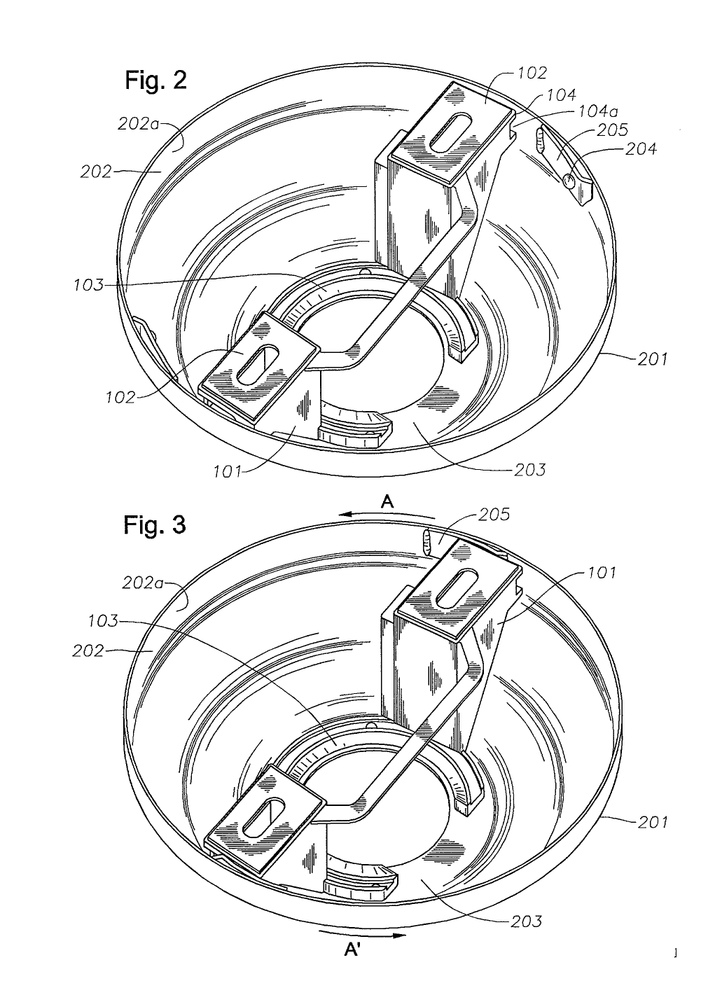

FIG. 2 shows the position of frame 101 and shroud 201 prior to the mating of receptacle 104a of frame 101 with projection 204 of shroud 201. As shown, shroud 201 is positioned to cover, or surround frame 101 such that second surface 104 of frame 101 is adjacent to inner surface 202a of flange 202, and similarly, skirt 103 of frame 101 is adjacent to rim surface 203 of shroud 201. Consequently, receptacle 104a and projection 204 are also aligned. According to the illustrated position of frame 101 and shroud 201, when frame 101 is mounted to a surface of a ceiling, shroud 201 will cover, or surround, the portions frame 101 which hung downwardly from the ceiling mount position.

FIG. 3 illustrates mounting assembly 100 with shroud 201 secured to frame 101, according to the present embodiment. As arrows A and A′ indicate, shroud 201 can be rotated in a counter clockwise direction, from a position shown in FIG. 2, and projection 204 (not shown) can interact with receptacle 104a (not shown) in a sliding manner. More specifically, as shroud 201 is rotated, projection 204 is slidably inserted into receptacle 104a. In the present embodiment, movable element 205, on which projection 204 is positioned, is inclined relative to inner surface 202a of flange 202 such that when receptacle 104a encounters movable element 205, a force from moveable element 205 against second surface 104 increases as second surface 104 travels over movable element 205. Thus, at the time when projection 204 is fully inserted into receptacle 104a, which occurs when projection 204 abuts an interior wall of receptacle 104a, a force of moveable member 205 against second surface 104 is at a maximum, and thus aids in retaining projection 204 in receptacle 205, and consequently, aids in securing shroud 201 to frame 101.

Although the present embodiment describes the operation of mounting assembly 100 wherein shroud 201 can be rotated to mate projection 204 provided thereon with receptacle 104a provided in frame 101, this is only because, in general, frame 101 will be mounted to a surface, and accordingly, will be impeded from movement. Conversely, however, frame 101 can rotate in shroud 201, which can be held fixed against rotation. Even further still, both frame 101 and shroud 201 can be rotated relative to each other. Moreover, the direction of rotation of either frame 101 and shroud 201 is also arbitrary.

In accordance with one aspect of the present embodiment, a mounting assembly can be constructed by first providing frame 101 which can be formed of any material including metal and plastic. Preferably, shroud 201 is constructed, or formed, according to the exterior dimensions of frame 101. In particular, shroud 201 is formed to be a cover that is suitable for covering frame 101. Projection 204 can be provided on an inner surface of shroud 201, while receptacle 104a, capable of mating with projection 204 of shroud 201, can be provided on frame 101. Alternatively, a projection can be provided on a surface of frame 101, whereas a receptacle can be provided on an inner surface of shroud 201.

Although the present invention has been described with reference to a presently preferred embodiment, it will be appreciated by those skilled in the art that various modifications, alternatives, variations, and substitution of parts and elements, may be made without departing from the spirit of the invention. Thus, the present application is intended to cover such modifications, alternatives, variations and elements as fall within the scope of the appended claims.

What is claimed is:

1. An assembly comprising:
a frame for mounting a fan to a surface, a surface of said frame provided with a receptacle therein; and
a shroud for covering said frame, an inner surface of said shroud provided with a projection for mating with said receptacle.

2. An assembly according to claim 1 wherein said projection is positioned on a spring element, which is positioned on said inner surface of said shroud.

3. An assembly according to claim 1 wherein an opening for a downrod is provided in each of said frame and said shroud.

4. An assembly for a ceiling fan comprising:
a frame having a first surface and a second surface, said second surface provided with a receptacle therein; and
a shroud having a flange, an inner surface of said flange having a projection provided thereon for mating with said receptacle,
wherein said shroud can be positioned to cover said frame such that said inner surface of said flange is positioned adjacent to said second surface of said frame, and said projection can be inserted into said receptacle.

5. An assembly according to claim 4 wherein said projection is positioned on a spring element, which is positioned on said inner surface of said flange.

6. An assembly according to claim 4 wherein an opening for a downrod assembly is provided in each of said frame and said shroud.

7. An assembly according to claim 4 wherein said projection can be inserted into said receptacle by aligning said projection and said receptacle and rotating said shroud with respect to said frame.

8. An assembly according to claim 4 wherein said first surface of said frame can be mounted to a surface.

9. An assembly according to claim 4 wherein said frame has a skirt and said shroud has a rim, and wherein said skirt can be positioned adjacent to said rim.

10. A method for making an assembly for attaching a ceiling fan to a surface comprising the steps of:
providing a frame having a first surface and a second surface; and
forming a shroud that is capable of covering said frame when said first surface of said frame is positioned on a surface,
wherein a projection is provided on an inner surface of said shroud, and a receptacle for mating with said projection is provided in said second surface of said frame.

11. A method according to claim 9 wherein said projection can be slidably inserted in said receptacle.

12. An assembly according to claim 10 wherein said frame has a skirt and said shroud has a rim, and wherein said skirt can be positioned adjacent to said rim.

13. A method according to claim 9 wherein said shroud has a flange, and said projection is provided on an inner surface of said flange.

14. A method according to claim 11 wherein said second surface of said frame can be positioned adjacent to said inner surface of said flange.
